(19) United States
(12) Patent Application Publication
(10) Pub. No.: US 2009/0110519 A1
(43) Pub. Date: Apr. 30, 2009

(54) Semiconductor manufacturing apparatus and method for loading/unloading wafer via variable setting of slot

(75) Inventors: Jong-Bum Park, Seongnam-si (KR); Kwang-Hee Shin, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/287,388

(22) Filed: Oct. 9, 2008

(30) Foreign Application Priority Data
Oct. 25, 2007 (KR) 10-2007-0107622

(51) Int. Cl. H01L 21/677

(52) U.S. Cl. 414/222.01

(57) ABSTRACT

A loading/unloading method of a semiconductor manufacturing apparatus for randomly designating a slot of a wafer in loading/unloading the wafer is provided. The method of loading and unloading a wafer through a random designation of wafer slot instead of sequential designation in a semiconductor manufacturing apparatus includes pre-setting a wafer slot selection mode; loading wafers into a piece of process equipment in the pre-set slot selection sequence when the wafer slot selection mode is set as a random mode; performing a process on the wafers; and unloading the wafers having been processed in a pre-set slot selection sequence, thereby preventing defects in the wafer.

### CROSS REFERENCE TO RELATED APPLICATIONS

This application claims priority under 35 U.S.C. §119 from Korean Patent Application 10-2007-0107622, filed in the Korean Intellectual Property Office on Oct. 25, 2007, the contents of which are hereby incorporated by reference in their entirety for all purposes as if fully set forth herein.

### BACKGROUND OF THE INVENTION

1. Technical Field

The present invention relates to semiconductor manufacturing apparatuses, and more particularly, to a semiconductor manufacturing apparatus and a wafer loading/unloading method thereof, for loading/unloading a wafer through a randomly variable setting of a wafer slot.

2. Description of the Related Art

In general, a wafer used in manufacturing a semiconductor device is repeatedly subjected to processes such as a cleaning, diffusion, photoresist coating, exposure, developing, etching, ion implantation, etc. In general, each process step is performed using a corresponding semiconductor manufacturing apparatus.

Semiconductor manufacturing apparatuses for performing the processes are disposed to perform respective unit processes, and in each corresponding unit process, wafers based on a unit of about 25 sheets constitute a lot of one unit, and undergo a selected process under a relatively optimum process condition. The wafers provided as a unit of one lot set inside a loadlock chamber are frequently moved into a cleaning chamber, reaction chamber, cooling chamber, etc., by a loader. The wafer loader removes each of the wafers numbered 1 to 25 in each slot of a carrier of the loadlock chamber and moves it to the reaction chamber or moves a wafer completed for a process from the reaction chamber to a corresponding slot of a carrier of the loadlock chamber

The wafer loader is generally constructed of a lead portion for performing an up/down operation of a transfer robot's entire assembly and a blade for lifting and unloading the wafer, and a gear and motor for a rotation, extend/retract and up/down operation etc., and further comprises a motor drive part for operating them corresponding to respective steps. When loading the wafer by the blade of the loader, the blade is inserted into the carrier to insert the wafer into the slot and then is moved down, and thus the wafer is placed in the slot and mounted thereon. Further, when the wafer is taken out of the carrier in an unloading operation, the blade is inserted into the carrier and the wafer mounted in the slot is lifted up slightly and then is mounted on the blade.

In such a semiconductor manufacturing apparatus, wafers are sequentially taken out of a lowermost part through an uppermost part of the carrier, and are transferred to process equipment, and then the process is performed. The wafers for which the process is completed are again loaded/unloaded from the lowermost slot of the carrier.

However, for example, when a wafer is set in an uppermost part of the carrier, the wafer has a relatively large exposed surface area. As a result, a defect occurrence rate in an outermost slot is very high and an error occurrence frequency is high due to an exposure time and environment before/after the process.

To solve this problem, wafers from a wafer set in an uppermost slot of the carrier to a wafer set in a lowermost part of the carrier are taken out sequentially, and the wafers are transferred to process equipment to perform the process, and the wafers on which the process is completed are again set first in an uppermost part of the carrier. That is, for example, when the process is performed first for wafer set in the lowermost part of the carrier, and even though particles are dropped onto the wafer on which the process is completed and contamination is caused thereon, the particles can be removed in a cleaning process to prevent a process error, but when particles are dropped onto a wafer that has not yet undergone the process, the process error cannot be prevented.

As described above, while the loader is continuously used for a long time, a moment teaching value may be distorted and a carrier may be not stably loaded in an index by a worker's mistake. At this time, the loader moves a robot arm by using a setting value to place or remove the wafer, but when the carrier is not stably mounted or the moment teaching is distorted, the robot arm may contact another wafer, causing a scratch on the face of wafer. At this time, particles are generated and are dropped to a wafer mounted in a lower part of the carrier, thus causing a quality error in the wafers.

In such conventional semiconductor manufacturing apparatus it is impossible to randomly load and unload wafers in a condition in which wafers mounted in the carrier are sequentially loaded/unloaded and undergo the experiment or sample work for the production thereof.

### SUMMARY OF THE INVENTION

Accordingly, some embodiments of the invention provide a semiconductor manufacturing apparatus and method for loading and unloading wafers by randomly setting, not sequentially setting, a wafer slot for the wafers mounted in a carrier.

According to a first aspect, the invention is directed to a semiconductor manufacturing apparatus for loading and unloading wafers. The apparatus includes: a carrier for individually mounting wafers in a plurality of slots; one or more pieces of process equipment for performing one or more respective semiconductor manufacturing processes on the supplied wafer; a loader for loading the wafers mounted in the carrier into one piece of process equipment, or unloading the wafers from the corresponding piece of process equipment into the carrier; and a controller for controlling the loader to sequentially load and unload the wafers in a slot number sequence corresponding to a mapping state of the wafer mounted in each slot when a slot selection mode is set to a normal mode, and controlling the loader to randomly load and unload the wafers in a pre-set slot selection sequence when the slot selection mode is set to a random mode.

In one embodiment, the apparatus further includes an operator interface server coupled to the controller for inputting a process condition to perform each process and starting a corresponding process, and executing a wafer slot selection determination program to set the slot selection mode.

According to another aspect, the invention is directed to a method of loading and unloading wafers through a variable setting of wafer slot in a semiconductor manufacturing apparatus, the method comprising: setting a wafer slot selection mode; loading wafers into a piece of process equipment in pre-set slot selection sequence when the wafer slot selection mode is set to a random mode; performing a process on the wafers; and unloading the wafers having been processed in a pre-set slot selection sequence.

In one embodiment, the setting of the wafer slot selection mode comprises: executing a wafer slot selection determination operation and to determine the wafer slot selection mode and displaying a result on a display; and inputting a random mode and a slot selection sequence and displaying a second result on the display.

As described above, according to some embodiments of the invention, wafers are loaded and unloaded through a random setting, not in a slot number sequence, when wafers mounted in a carrier are loaded or wafers are unloaded into the carrier through an operator interface server before performing a specific process, thereby preventing an occurrence of error in the wafer, even when particles generated by a scratch effect of wafer due to a teaching error are dropped to a wafer mounted in a lower slot, and additionally preventing a defect occurrence caused by surface exposure of a wafer mounted in an uppermost slot by loading and unloading wafers in a slot number sequence.

Additionally, in sampling and testing wafers according to a large-sized diameter tendency of 8 to 12 inches, a plurality of wafers mounted in a carrier can be randomly sampled and then loaded/unloaded, thereby obtaining a random sampling without manual work.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 schematically illustrates a semiconductor manufacturing apparatus according to an embodiment of the invention.

FIG. 2 is a flowchart illustrating a process to determine a wafer slot selection mode according to an embodiment of the invention.

FIG. 3 contains an illustration for a screen display state to determine a wafer slot selection mode according to an embodiment of the invention.

FIG. 4 is a flowchart illustrating a process for random loading and unloading of a wafer according to a setting of a wafer slot selection mode according to an embodiment of the invention.

### DETAILED DESCRIPTION

Embodiments of the present invention now will be described more fully hereinafter with reference to the accompanied drawings. This invention may, however, be embodied in many different forms and should not be construed as limited to the embodiments set forth herein. Rather these embodiments are provided so that this disclosure will be thorough and complete, and will fully describe the invention to those skilled in the art.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

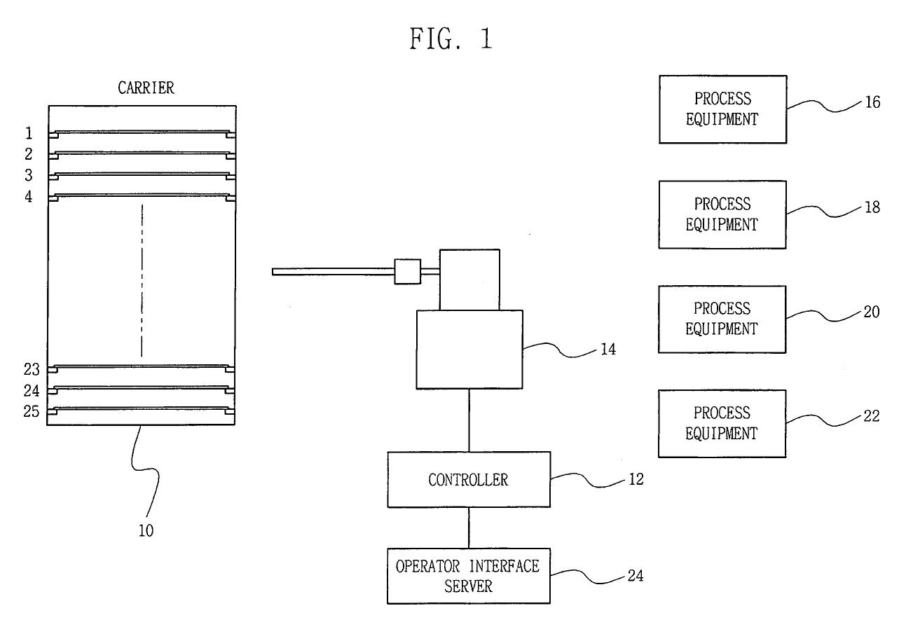

FIG. 1 schematically illustrates a semiconductor manufacturing apparatus according to an embodiment of the invention. Referring to FIG. 1, the semiconductor manufacturing apparatus includes a carrier 10 with a plurality of slots in which wafers are individually set and which are positioned with an equal interval therebetween. A plurality of pieces of process equipment 16, 18, 20 and 22 are provided to perform semiconductor fabrication processes on supplied wafers.

A loader 14 loads wafers in the carrier 10 or unloads wafers from each piece of process equipment 16, 18, 20 or 22 to the inside of the carrier 10 when processes performed by each piece of process equipment are completed on the wafers.

A controller 12 controls the loader 14 to sequentially perform loading and unloading of wafers in a slot number sequence corresponding to a mapping state of the wafer set in each slot when a mapping sensor(not shown) senses a wafer mapping state and a slot selection mode is set to a normal mode. The controller also controls the loader 14 to randomly load or unload the wafers into or from slots in a pre-set slot selection sequence when the slot selection mode is set to a random mode.

An operator interface server 24 is coupled to the controller 12 and inputs a process condition for each process to start a corresponding process, and sets a slot selection mode by executing a wafer slot sequence determination program.

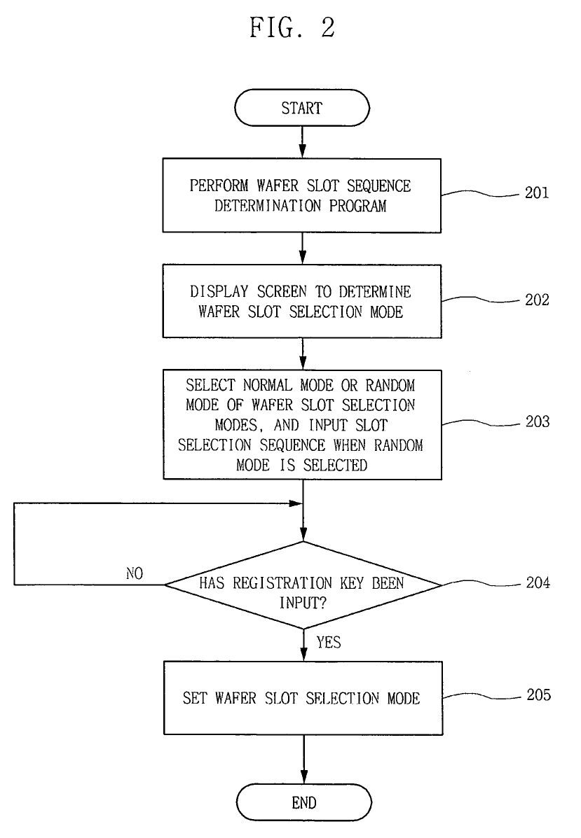

FIG. 2 is a control flowchart illustrating a process to determine a wafer slot selection mode according to an embodiment of the invention.

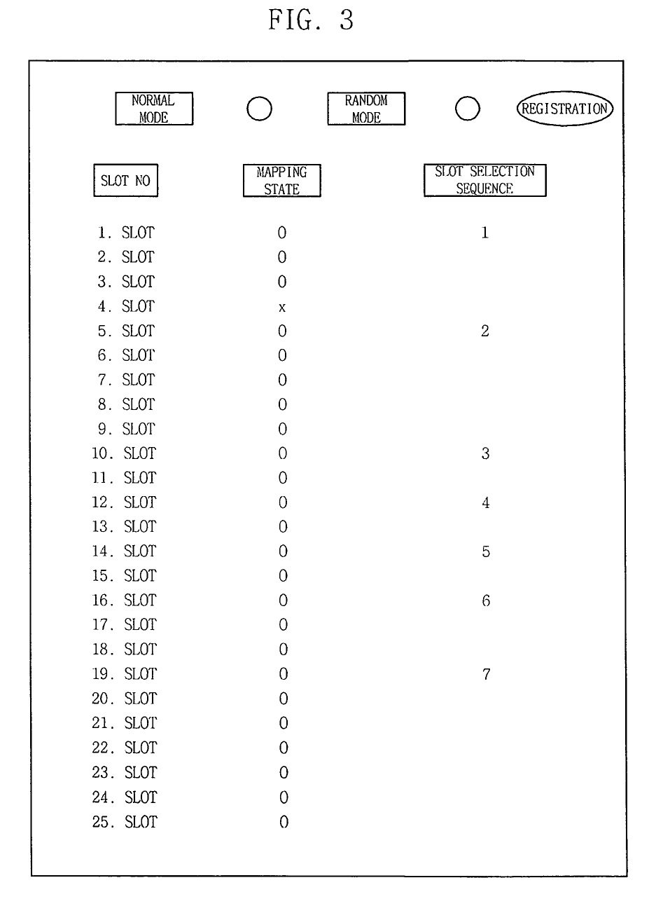

FIG. 3 provides an illustration for a screen display state to determine a wafer slot selection mode according to an embodiment of the invention.

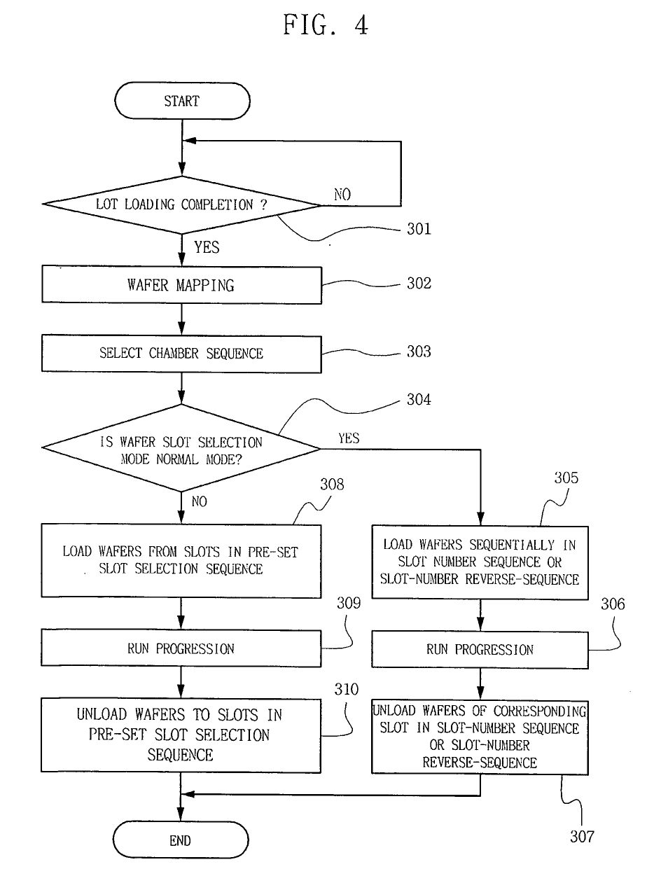

FIG. 4 is a control flowchart illustrating a process for random loading and unloading of wafers according to a setting of wafer slot selection mode according to an embodiment of the invention.

Referring to FIGS. 1 to 4, according to the invention, when an operator such as an engineer inputs an execution command of a wafer slot sequence determination program, operator interface server 24 executes a wafer slot sequence determination program in step 201. In step 202, the operator interface server 24 presents a screen to determine a wafer slot selection mode as shown in FIG. 3. In step 203, when the operator manipulates a key input, the operator interface server 24 selects and indicates one of normal mode and random mode on the screen, and when selecting the random mode, a slot selection sequence number is displayed on the screen. In step 204, the operator interface server 24 determines whether a registration key has been input, and when the registration key has been input, step 205 is performed. In step 205, the operator interface server 24 transmits slot selection mode information to controller 12 to set the wafer slot selection mode. Here, in inputting the slot selection sequence, a slot can be selected optionally by a required sequence. For example, a first slot can be first selected, and a tenth slot can be selected secondly, and a twelfth slot can be selected thirdly.

Referring to FIG. 4, an operation of loading and unloading a wafer after determining a wafer slot selection mode is performed. In step 301, the controller 12 checks whether the loading is completed. When the loading of lot is completed, in step 302, the controller 12 performs a mapping of the wafer through a mapping sensor, and stores mapping result information in a memory. In step 303, a chamber sequence to supply the wafer to a plurality of pieces of process equipment 16, 18, 20, 22 is selected. In step 304, it is determined whether the wafer slot selection mode is set as a normal mode. When set as the normal mode, in step 305, the controller 12 performs a control so that wafers mounted in the carrier are sequentially loaded in a slot number sequence or a reverse order of the slot number. The wafer mounted in the carrier is loaded and is transferred to one piece of process equipment 16, 18, 20 or 22, and a run operation is performed in step 306. When the run operation is completed, the controller 12 controls wafers having been processed in the corresponding piece of process equipment 16, 18, 20, or 22 is completed to be again sequentially unloaded in the slot number sequence or reverse order of the slot number in a step 307.

In step 304, if it is determined that the slot selection mode is a random mode and not the normal mode, the controller 12 loads the wafers mounted in the carrier in a pre-set slot selection sequence in step 308. The wafers mounted in the carrier are loaded and transferred to one piece of process equipment 16, 18, 20 or 22 through such method, and a run operation is performed in step 309. When the run operation is completed, the controller 12 operates in step 310 so that wafers completed in the process are again unloaded in a pre-set slot selection sequence from the corresponding piece of process equipment 16, 18, 20, or 22 in step 310.

As described above, according to some embodiments of the invention, wafers are loaded and unloaded by employing a random setting instead of a slot number sequence, thereby preventing an error occurrence in wafers and obtaining a random sampling without manual work.

It will be apparent to those skilled in the art that modifications and variations can be made in the present invention without deviating from the spirit or scope of the invention. Thus, it is intended that the present invention cover any such modifications and variations of this invention provided they come within the scope of the appended claims and their equivalents. Accordingly, these and other changes and modifications are seen to be within the true spirit and scope of the invention as defined by the appended claims.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A semiconductor manufacturing apparatus for loading and unloading wafers, the apparatus comprising:
a carrier for individually mounting wafers in a plurality of slots;
one or more pieces of process equipment for performing one or more respective semiconductor manufacturing processes on the supplied wafer;
a loader for loading the wafers mounted in the carrier into one piece of process equipment, or unloading the wafers from the corresponding piece of process equipment into the carrier; and
a controller for controlling the loader to sequentially load and unload the wafers in a slot number sequence corresponding to a mapping state of the wafer mounted in each slot when a slot selection mode is set to a normal mode, and controlling the loader to load and unload the wafers in a pre-set slot selection sequence when the slot selection mode is set to a random mode.

2. The apparatus of claim 1, further comprising an operator interface server coupled to the controller for inputting a process condition to perform each process and starting a corresponding process, and executing a wafer slot sequence determination program to set the slot selection mode.

3. A method of loading and unloading wafers through a variable setting of wafer slot in a semiconductor manufacturing apparatus, the method comprising:
setting a wafer slot selection mode;
loading wafers into a piece of process equipment in pre-set slot selection sequence when the wafer slot selection mode is set to a random mode;
performing a process on the wafers; and
unloading the wafers having been processed in a pre-set slot selection sequence.

4. The method of claim 3, wherein the setting of the wafer slot selection mode comprises:
executing a wafer slot selection determination operation and to determine the wafer slot selection mode and displaying a result on a display; and
inputting a random mode and a slot selection sequence and displaying a second result on the display.
